(19) United States
(12) Patent Application Publication
(10) Pub. No.: US 2008/0017100 A1
(43) Pub. Date: Jan. 24, 2008

(54) Method for fabricating single-crystal GaN based substrate

(75) Inventors: Jen-Inn Chyi, Jhongli City (TW); Guan-Ting Chen, Jhongli City (TW)

Correspondence Address: TROXELL LAW OFFICE PLLC, SUITE 1404, 5205 LEESBURG PIKE, FALLS CHURCH, VA, 22041, US

(73) Assignee: National Central University, Taoyuan (TW)

(21) Appl. No.: 11/526,067

(22) Filed: Sep. 25, 2006

(30) Foreign Application Priority Data
Jul. 20, 2006 (TW) 095126486

(51) Int. Cl. C30B 23/00

(52) U.S. Cl. 117/104; 117/108; 117/88

(57) ABSTRACT

A GaN based substrate is obtained with a simple etching. The GaN based substrate is separate from another base substrate with the etching. The whole process is easy and costs low. The substrate is made of a material having a matching lattice length for a lattice structure so that the substrate has good characteristics. And the GaN based substrate has good heat dissipation so that the stability and life-time of GaN based devices on the GaN based substrate are enhanced even when they are constantly operated under a high power.

### FIELD OF THE INVENTION

The presented invention relates to fabricating a substrate; more particularly, relates to easily separating a GaN based substrate from a base substrate.

### DESCRIPTION OF THE RELATED ARTS

A prior art of a substrate of single crystal GaN is obtained through a metal-organic chemical vapor deposition or a hydride vapor phase epitaxy, where a GaN based material is deposited on a base substrate and then the GaN based material is separated from the base substrate by illuminating the interface with a laser to obtain a single crystal GaN substrate, as shown in FIG. 3A and FIG. 3B. In another word, a general single crystal GaN substrate is obtained by firstly growing a GaN based material 32 on a base substrate 31. Then a laser 33 is applied to heat up an interface between the base substrate 31 and the GaN based material 32 to decompose the GaN into gallium and nitrogen. Then the base substrate 31 is heated to the melting point of gallium so that the GaN based material 32 is separated from the base substrate. The GaN based material 32 is obtained after the separation, which is a single crystal GaN substrate. Yet a disadvantage of this method is about applying the laser to heat the interface for the separation, which results in a long time of process and a high cost when fabricating a large size GaN based substrate.

Another prior art is shown in FIG. 4, where a buffer layer 42 and a GaN epitaxial layer 43 are grown on a base substrate 41; after fabricating a patterned mask 44 on a surface of the GaN epitaxial layer 43, an etching is performed on the buffer layer 42 and the GaN epitaxial layer 43 until the base substrate 41; then a GaN based material 45 is grown laterally and upwardly, where the patterned mask 44 has a width and length below 1 micron to obtain a structural fragile point of the buffer layer 42. Then, through a process of heating, the GaN based substrate is separated from the base substrate 41 because of a large difference of thermal expansion coefficient of lattice between the base substrate 41 and that of the buffer layer 42. And the GaN based material 45 obtained after the separation is a single crystal GaN substrate. Yet the above method requires a patterned mask 44 defined through a transparent media adapter (TMA); and a GaN based material 45 has to be grown after etching the GaN to the bottom. All these steps take time and cost much.

The above prior arts both fabricate a GaN based substrate accompanying a longtime of processing and a high cost. Hence, the prior arts do not fulfill users' requests on actual use.

### SUMMARY OF THE INVENTION

The main purpose of the present invention is to easily separate a GaN based substrate from a base substrate by a simple etching with a simple fabrication process and a low cost.

Another purpose of the present invention is to provide a method for separating a single crystal GaN based substrate from a base substrate, where the single crystal GaN based substrate has low dislocation density crystal to grow the GaN based substrate on the base substrate with a lattice length matching a lattice structure for obtaining good characteristics.

The other purpose of the present invention is to provide a method for separating a single crystal GaN based substrate from a base substrate, where a single crystal GaN based substrate has a good heat dissipation to enhance its stability and life-time even being operated under a high power.

To achieve the above purposes, the present invention is a method for fabricating single-crystal GaN based substrate, comprising steps of:

(a) obtaining a base substrate;

(b) growing oxide nanorods on the base substrate;

(c) growing a GaN based material on the oxide nanorods to obtain a structure having a GaN based substrate; and

(d) etching the oxide nanorods with an etching solution applied to the structure to separate the GaN based substrate from the base substrate.

Therein, the base substrate in step (a) is made of sapphire, MgO, ZnO Si, quartz, SiC or GaAs; the oxide nanorods in step (b) are made of ZnO, MgO, MgZnO, LiAlO2, LiGaO2, Li2SiO3, Li2GeO3, NaAlO2, NaGaO2, Na2GeO3, Na2SiO3, Li3PO4, Li3AsO4, Li3VO4, Li2MgGeO4, Li2ZnGeO4, Li2CdGeO4, Li2MgSiO4, Li2ZnSiO4, Li2CdSiO4, Na2MgGeO4, Na2ZnGeO4 or Na2ZnSiO4; an oxide component of the oxide nanorods in step (b) is an oxide of Be, B, N, Cr, Mn, Fe, Co, Ni, Cu, In or Sb; the oxide nanorods in step (b) are grown through a molecular beam epitaxy, a metal-organic chemical vapor deposition or a hydride vapor phase epitaxy; the GaN based material in step (c) is GaN, AlGaN, InGaN or AlGaInN; the GaN based material in step (c) are grown through a molecular beam epitaxy, a metal-organic chemical vapor deposition or a hydride vapor phase epitaxy; the etching solution in step (d) is a solution for etching oxide, such as a potassium hydroxide solution; and the separation of the GaN based substrate from the base substrate in step (d) can also be done through applying a stress to break the oxide nanorods to separate the GaN based substrate from the base substrate.

Accordingly, a novel method for fabricating single-crystal GaN based substrate is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the view showing the flow chart of the preferred embodiment according to the present invention;

FIG. 2A to FIG. 2D a re the views showing the structures in step (a), step (b), step (c) and step (d) separately;

FIG. 3A and FIG. 3B are the first and the second structural views of a prior art; and

FIG. 4 is the structural view of another prior art.

### DESCRIPTION OF THE PREFERRED EMBODIMENT

The following description of the preferred embodiment is provided to understand the features and the structures of the present invention.

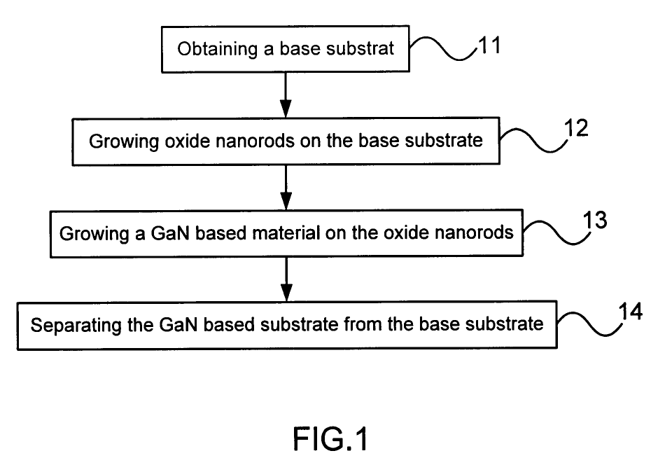

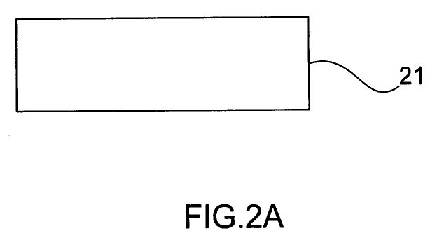

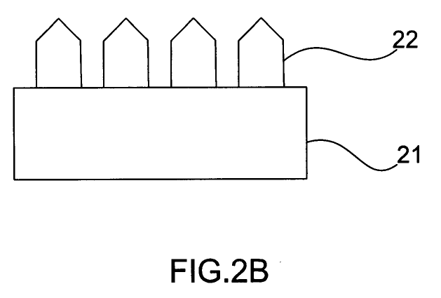

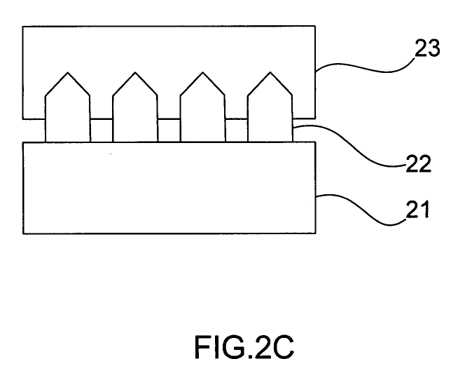

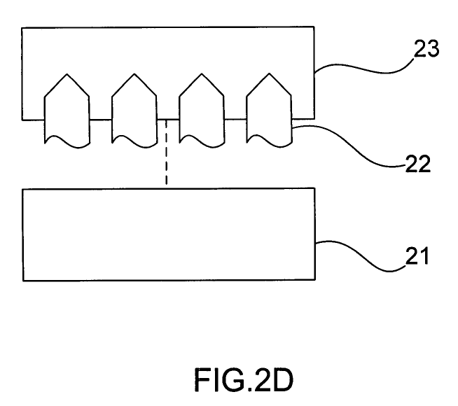

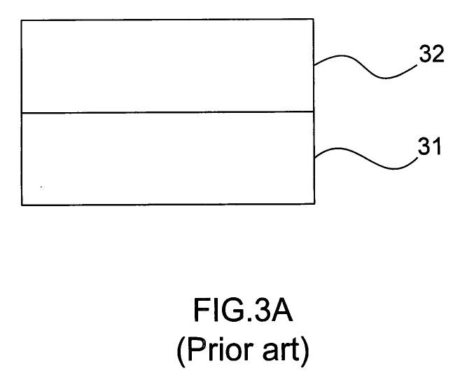

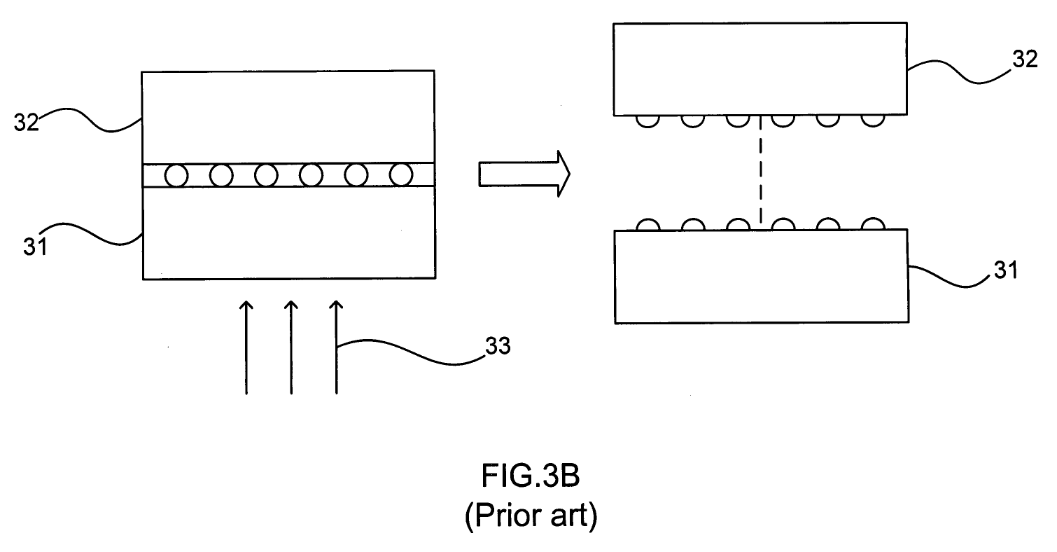

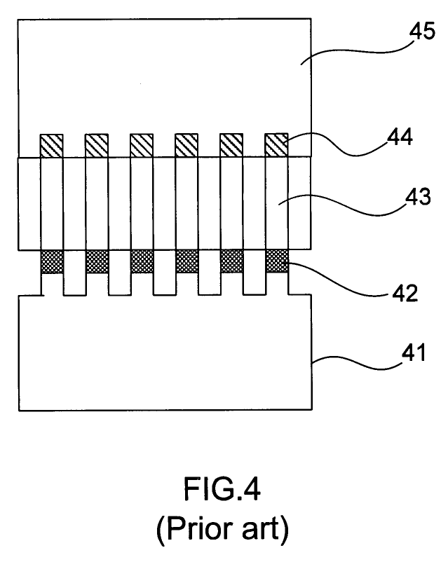

Please refer to FIG. 1 and FIG. 2A to FIG. 2D, which are views showing a flow chart of the preferred embodiment and structures in step (a), step (b), step (c) and step (d) separately according to the present invention. As shown in the figures, the present invention is a method for fabricating single-crystal GaN based substrate, comprising the following steps:

(a) Obtaining a base substrate 11: A base substrate 21 is obtained from a material of sapphire, MgO, ZnO, Si, quartz, SiC or GaAs.

(b) Growing oxide nanorods on the base substrate 12: Oxide nanorods 22 are grown on the base substrate 21, where the growth of the oxide nanorods is obtained by a molecular beam epitaxy, a metal-organic chemical vapor deposition or a hydride vapor phase epitaxy; the oxide nanorods 22 is made of ZnO, MgO, MgZnO, LiAlO₂, LiGaO₂, Li₂SiO₃, Li₂GeO₃, NaAlO₂, NaGaO₂, Na₂GeO₃, Na₂SiO₃, Li₃PO₄, Li₃AsO₄, Li₃VO₄, Li₂MgGeO₄, Li₂ZnGeO₄, Li₂CdGeO₄, Li₂MgSiO₄, Li₂ZnSiO₄, Li₂CdSiO₄, Na₂MgGeO₄, Na₂ZnGeO₄ or Na₂ZnSiO₄. And an oxide component of the oxide n anorods 22 is an oxide of Be, B, N, Cr, Mn, Fe, Co, Ni, Cu, In or Sb.

(c) Growing a GaN based material on the oxide nanorods 13: A GaN based material is grown on the oxide nanorods to obtain a structure having a GaN based substrate 23, where the GaN based material is GaN, AlGaN, InGaN or AlGaInN; and the GaN based material is grown on the oxide nanorods 22 through a molecular beam epitaxy, a metal-organic chemical vapor deposition or a hydride vapor phase epitaxy.

(d) Separating the GaN based substrate from the base substrate 14: An etching solution is applied to the structure having the GaN based substrate 23 to etch the oxide n a no rods 22 for separating the GaN based substrate 23 from the base substrate 21, where the etching solution is a solution for etching oxide, such as a potassium hydroxide solution. Or, another way to separate a stress the Ga N based substrate 23 from the base substrate 21 is to apply a stress to break the oxide nanorods 22 to separate the GaN based substrate 23 from the base substrate 21.

To sum up, the present invention is a method for fabricating single-crystal GaN based substrate, where, through a simple etching, a GaN based substrate is separated with a simple fabrication process and a low cost; the GaN based material in the substrate has a matching lattice length for a lattice structure to obtain good characteristics; and the GaN based substrate has a good heat dissipation to enhance its stability and life-time even being operated under a high power.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method for fabricating single-crystal gallium nitride (GaN) based substrate, comprising steps of:
(a) obtaining a base substrate;
(b) growing oxide nanorods on said base substrate;
(c) growing a GaN based material on said oxide nanorods to obtain a structure having a GaN based substrate; and
(d) etching said oxide nanorods of said structure with an etching solution to separate said GaN based substrate from said base substrate.

2. The method according to claim 1,
wherein said base substrate in step (a) is made of a material selected from a group consisting of sapphire, MgO, ZnO, Si, quartz, SiC and GaAs.

3. The method according to claim 1,
wherein said oxide nanorods in step (b) are made of a material selected from a group consisting of ZnO, MgO, MgZnO, LiAlO₂, LiGaO₂, Li₂SiO₃, Li₂GeO₃, NaAlO₂, NaGaO₂, Na₂GeO₃, Na₂SiO₃, Li₃PO₄, Li₃AsO₄, Li₃VO₄, Li₂MgGeO₄, Li₂ZnGeO₄, Li₂CdGeO₄, Li₂MgSiO₄, Li₂ZnSiO₄, Li₂CdSiO₄, Na₂MgGeO₄, Na₂ZnGeO₄ and Na₂ZnSiO₄.

4. The method according to claim 3,
wherein an oxide component of said oxide nanorods is an oxide of an element selected from a group consisting of Be, B, N, Cr, Mn, Fe, Co, Ni, Cu, In and Sb.

5. The method according to claim 1,
wherein said oxide nanorods in step (b) are grown through a method selected from a group consisting of a molecular beam epitaxy, a metal-organic chemical vapor deposition and a hydride vapor phase epitaxy.

6. The method according to claim 1,
wherein said GaN based material in step (c) is selected from a group consisting of GaN, AlGaN, InGaN and AlGaInN

7. The method according to claim 1,
wherein said GaN based material in step (c) are grown through a method selected from a group consisting of a molecular beam epitaxy, a metal-organic chemical vapor deposition and a hydride vapor phase epitaxy.

8. The method according to claim 1,
wherein said etching solution in step (d) is a potassium hydroxide solution.

9. The method according to claim 1,
wherein said separation of said GaN based substrate from said base substrate in step (d) is done through applying a stress to break said oxide nanorods to separate said GaN based substrate from sa id base substrate.
